(19) United States
(12) Patent Application Publication
(10) Pub. No.: US 2014/0145734 A1
(43) Pub. Date: May 29, 2014

(54) Capacitor Sensing Circuit

(71) Applicant: SITRONIX TECHNOLOGY CORP., Zhubei City (TW)

(72) Inventors: Meng Yong LIN, Zhubei City (TW); Ming-Huang LIU, Zhubei City (TW); Wei Yang OU, Zhubei City (TW)

(73) Assignee: SITRONIX TECHNOLOGY CORP., Zhubei City (TW)

(21) Appl. No.: 13/796,024

(22) Filed: Mar. 12, 2013

(30) Foreign Application Priority Data
Nov. 26, 2012 (TW) 101144185

(51) Int. Cl. G01R 27/26

(52) U.S. Cl. CPC G01R 27/2605
USPC 324/684

(57) ABSTRACT

The present invention provides a capacitor sensing circuit, comprising a driving unit, a switching unit, a differential integrator circuit, and a post-processing circuit. The driving unit is for providing driving signals and timing required by the capacitor sensing circuit, the switching unit switches signals according to two inverting timings, φ₁ and φ₂, the driving unit drives the capacitor sensing circuit, and together with the positive/negative input terminals of the differential integrator circuit, the signals are accumulated and integrated in both timing φ₁ and φ₂. The post-processing circuit receive the differential output of the differential integrator circuit for processing and/or utilizing the signals. The two timing signals are time-sharing signals in a period. Therefore, the capacitor sensing circuit is not effected by the common mode noise, and the accuracy and the sensibility are increased.

### FIELD OF THE INVENTION

The present invention generally relates to a capacitor sensing circuit, and more particularly, certain embodiments of the invention relate to a capacitor sensing circuit comprising a plurality of capacitors.

### BACKGROUND OF THE INVENTION

According to the capacitance characteristic formula, the capacitance relates to the distance between the electrode plates, therefore, the major theory for implementing capacitor sensing is to link the physical distance with the capacitance. Nowadays, many circuits apply capacitor sensing therein, such as G-sensor, accelerometer, capacitive touch panel, etc. The sensed capacitance or capacitance variation is used for calculating the gravity, accelerometer, or determining pressing.

Generally, most of the circuits applying capacitor sensing configure several capacitors for multi-dimensional sensing to identify the variation of the physical distance on each dimension, such as at least one capacitor for sensing the variation of the accelerate along a single direction, X or Y axis. Therefore, the capacitor sensing is performed by sequentially sensing the capacitor(s) for the directions one by one, and then the sensed values are required for processing. Such procedures take much time. Meanwhile, the accuracy of the sensed values is effected by the common mode noise. Therefore, there is needed to raise the efficiency as well as the accuracy for multi-dimensional capacitor sensing.

### SUMMARY OF THE INVENTION

One aspect of the present invention is to provide a capacitor sensing circuit, through the switching unit processes the inverting timing signals to drive the capacitor sensing unit, the sensing signals can be inputted throughout the whole driving period. The differential integrator circuit also receives differential output signals throughout the whole driving period without affected by common mode noise to raise precision and sensitivity.

In one aspect of the invention, an embodiment of the invention is provided that a capacitor sensing circuit proceeds capacitor sensing of different capacitors to shorten required time for sensing and raise the efficiency through a plurality of time-sharing timing signals with respect to the period thereof.

According to the present invention, a capacitor sensing circuit comprises: a driving unit, a switching unit, a capacitor sensing unit, a differential integrator circuit, and a post-processing circuit. The driving unit provides required driving signals to the capacitor sensing circuit, and comprises a first timing signal and a second timing signal which is the inverting-phase signal of the first timing signal to generate driving voltages with reverse levels; the capacitor sensing unit receives the levels of the driving voltages provided by the driving unit to generate at least one first sensing signal corresponding to the first timing signal and at least one second sensing signal corresponding to the second timing signal; the switching unit is positioned between the capacitor sensing unit and the differential integrator circuit; the differential integrator circuit comprises two input terminals. The switching unit outputs the first sensing signal to an input terminal of the differential integrator circuit and the second sensing signal to another input terminal of the differential integrator circuit. One of the input terminals of the differential integrator circuit receiving the first sensing signal outputs a first integrated output signal, the other of the input terminals of the differential integrator circuit receiving the second sensing signal outputs a second integrated output signal. The post-processing circuit receives the first and second integrated output signals from the differential integrator circuit for signal processing or utilizing. The first and second timing signals are time-sharing timing signals with regard to the period thereof.

In one aspect of the invention, an embodiment of the invention is provided that the driving unit is for providing driving signals required by the capacitor sensing unit. The capacitor sensing unit is exemplarily comprised of two differential pair capacitors in the basic structure; here the differential pair capacitors are called by a first capacitor and a second capacitor. The differential pair capacitors require different voltage level variation for generating signals, therefore a first timing signal and a second timing signal which is the inverting-phase signal of the first timing signal are provided for generating required switching voltage level. At least one first sensing signal related to the capacitance of the first capacitor and/or the conjugate value of the capacitance of the second capacitor is outputted corresponding to the first timing signal, and at least one second sensing signal related to the capacitance of the second capacitor and/or the conjugate value of the capacitance of the first capacitor is outputted corresponding to the second timing signal. The switching unit switches the first sensing signal and the inverting-phase second sensing signal to the positive/negative input terminals of the differential integrator circuit correspondingly. For example, corresponding to the first timing signal, the positive input terminal is switched, and corresponding to the second timing signal, the negative input terminal is switched. The conjugate signals generated under the inverting-phase control are switched to input to the inverting-phase positive/negative input terminals, and then the two sensing signals, in the form of differential output, generated from the two inverting-phase timing signals are accumulated and integrated upon the differential integrator circuit. The post-processing circuit receives the differential output signals of the differential integrator circuit to carry out signal processing and/or utilizing.

Here, the capacitor sensing circuit is not limited to any specific type. For example, the capacitor sensing circuit could be chosen from any of the types of single-transmitter, dual-transmitter, single-receiver, dual-receiver, or other multi-transmitter/receiver. The application of the capacitor sensing circuit is for example but not limited to G-sensor, accelerometer, capacitive touch panel or the like. According to an embodiment of the present invention, the first capacitor and the second capacitor could receive the first timing signal and the second timing signal through a common route, such as the single-transmitter type, or respective routes, such as the dual-transmitter type.

Please noted that the capacitor sensing unit driven by the driving unit could further comprises more capacitors, such as four capacitors for the dual-transmitter dual-receiver type. It is assumed that a third capacitor in a reversely series connection with the first capacitor and a fourth capacitor in a reversely series connection with the second capacitor are comprised. The driving unit outputs a first sensing signal related to the difference between the capacitance of the first capacitor and the conjugate value of the capacitance of the third capacitor is outputted corresponding to the first timing signal, and a second sensing signal related to the difference between the capacitance of the second capacitor and the conjugate value of the capacitance of the fourth capacitor is outputted corresponding to the second timing signal.

In one aspect of the invention, an embodiment of the invention is provided that the switching unit, positioned between the capacitor sensing unit and the differential integrator circuit, switches corresponding to the first timing signal to allow the differential integrator circuit receiving the first sensing signal, and switches corresponding to the second timing signal to allow the differential integrator circuit receiving the second sensing signal to input different sensing signals to corresponding input terminals according to different timing. The details of the switching unit is not limited to any specific structure, but open to proper adjustments depending on the electrical connections of the first capacitor, second capacitor, and differential integrator circuit of the capacitor sensing unit. Preferably, the switching unit controls the output of the first sensing signal to an input terminal of the differential integrator circuit corresponding to the first timing signal, and the output of the second sensing signal to another input terminal of the differential integrator circuit corresponding to the second timing signal.

With regard to the characters of the first sensing signal and second sensing signal, an embodiment of the invention is provided that the driving unit could output a first sensing signal corresponding to the difference between the capacitance of the first capacitor and the conjugate value of the capacitance of the second capacitor corresponding to the first timing signal, and a second sensing signal corresponding to the difference between the capacitance of the second capacitor and the conjugate value of the capacitance of the first capacitor corresponding to the second timing signal in the single-transmitter type. However, another embodiment of the invention is provided that the two input terminals of the differential integrator circuit are utilized for an input terminal receiving the first sensing signal related to the capacitance of the first capacitor and another input terminal receiving the first sensing signal related to the conjugate value of the capacitance of the second capacitor corresponding to the first timing signal, and an input terminal receiving the second sensing signal related to the capacitance of the second capacitor and another input terminal receiving the second sensing signal related to the conjugate value of the capacitance of the first capacitor corresponding to the second timing signal in the dual-transmitter type. Then, at the same time, the capacitances of different capacitors are contributed to a more balanced sensing result. The switching unit could control the two first sensing signals to input to the input terminals of the differential integrator circuit respectively corresponding to the first timing signals, and control the two second sensing signals to reversely input to the input terminals of the differential integrator circuit respectively corresponding to the second timing signals.

The differential integrator circuit could perform the integration for the input signals of the input terminals to obtain the integrated output signals related to the difference between the input signals. Preferably, the differential integrator circuit is comprised of but not limited to two-ports differential operational amplifiers constructed to form an integrator circuit for additionally amplifying the signals to raise the sensibility. In companied with the at least one first sensing signal related to the capacitance of the first capacitor and/or the conjugate value of the capacitance of the second capacitor received corresponding to the first timing signal and the at least one second sensing signal related to the capacitance of the second capacitor and/or the conjugate value of the capacitance of the first capacitor, received corresponding to the second timing signal, the differential integrator circuit could compare the sensing signals in the different timings in one single period to shorten the required time for sensing several capacitors and raise the efficiency.

Further, for raising the precision, the voltages of the first capacitor and second capacitor could be additionally reset according to a reset timing signal. The reset timing signal could be a time-sharing timing signal of the first timing signal and second timing signal with regard to the period thereof.

After the capacitor sensing circuit gets the differential output signals through the differential integrator circuit, the post-processing circuit of any type could carried out differential signal processing or utilize the differential output signals. Here the details of the post-processing circuit is not limited to but for example comprised of any combination of an analog-digital converter, demodulator, buffer or the like.

Therefore, the capacitor sensing circuit and differential integrator circuit thereof in the present invention could obtain the differential output signals related to the first capacitor and second capacitor to raise the precision and sensibility of the capacitor sensing circuit without affected by the common mode noise.

### BRIEF DESCRIPTION OF THE DRAWINGS

Various objects and advantages of the present invention will be more readily understood from the following detailed description when read in conjunction with the appended drawing, in which:

FIG. 1 shows a block diagram of a capacitor sensing circuit of a first embodiment according to the present invention.

FIG. 2 shows a signal timing diagram for the reset timing signal φ_{0, first} timing signal φ₁, and second timing signal φ₂.

FIG. 3 shows a block diagram of a single-transmitter dual-receiver capacitor sensing circuit.

FIG. 4 shows a block diagram of a capacitor sensing circuit of a second embodiment according to the present invention.

FIG. 5 shows a block diagram of a capacitor sensing circuit of a third embodiment according to the present invention.

FIG. 6 shows a block diagram of a capacitor sensing circuit of a fourth embodiment according to the present invention.

### DESCRIPTION OF EMBODIMENTS OF THE INVENTION

Please refer to FIG. 1, which shows a block diagram of a capacitor sensing circuit of a first embodiment according to the present invention. Here the capacitor sensing circuit 1 is not limited to any specific type. For example, the capacitor sensing circuit could be chosen from any of the types of single-transmitter, dual-transmitter, single-receiver, dual-receiver, or other multi-transmitter/receiver. The application of the capacitor sensing circuit 1 is for example but not limited to G-sensor, accelerometer, capacitive touch panel or the like. As shown in FIG. 1, here the capacitor sensing circuit 1 is of an exemplary dual-transmitter single-receiver type, comprising a driving unit 10, a capacitor sensing unit 11, a switching unit 12, a differential integrator circuit 13, and a post-processing circuit 14.

The driving unit 10 provides driving signals V₁ and V₂ required by the capacitor sensing unit 1 for generating voltage levels Refp and Refn for driving alternately through a first timing signal φ₁ and a second timing signal φ₂. During the first timing signal φ₁, V₁=Refp/V₂=Refn, and during the second timing signal φ₂, V₁=Refn/V₂=Refp.

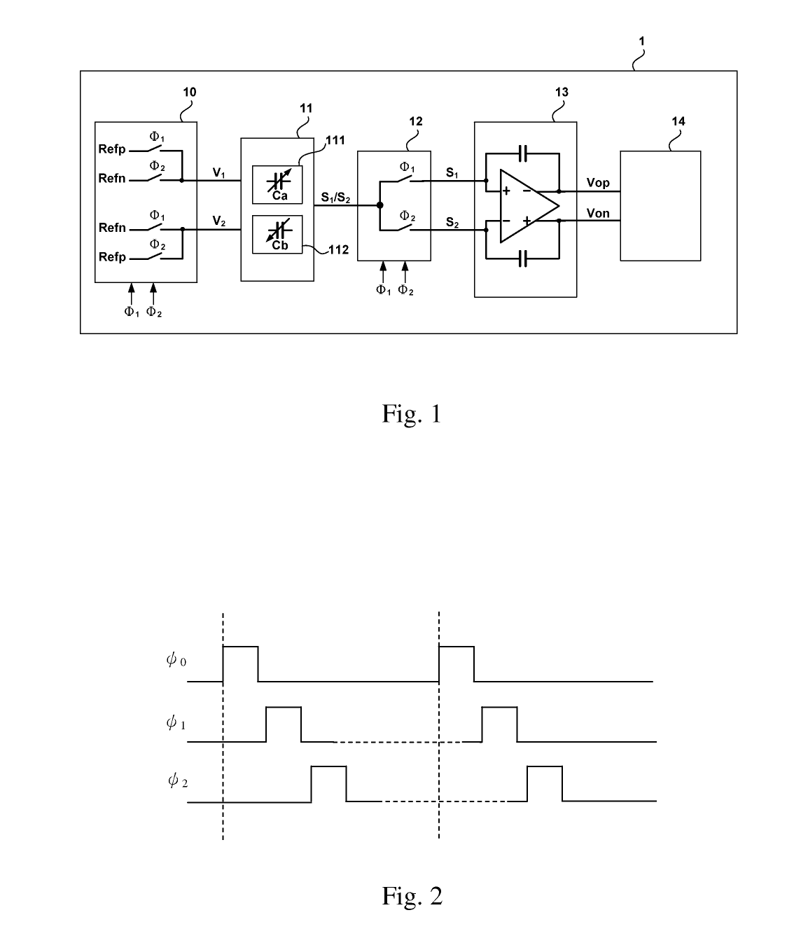

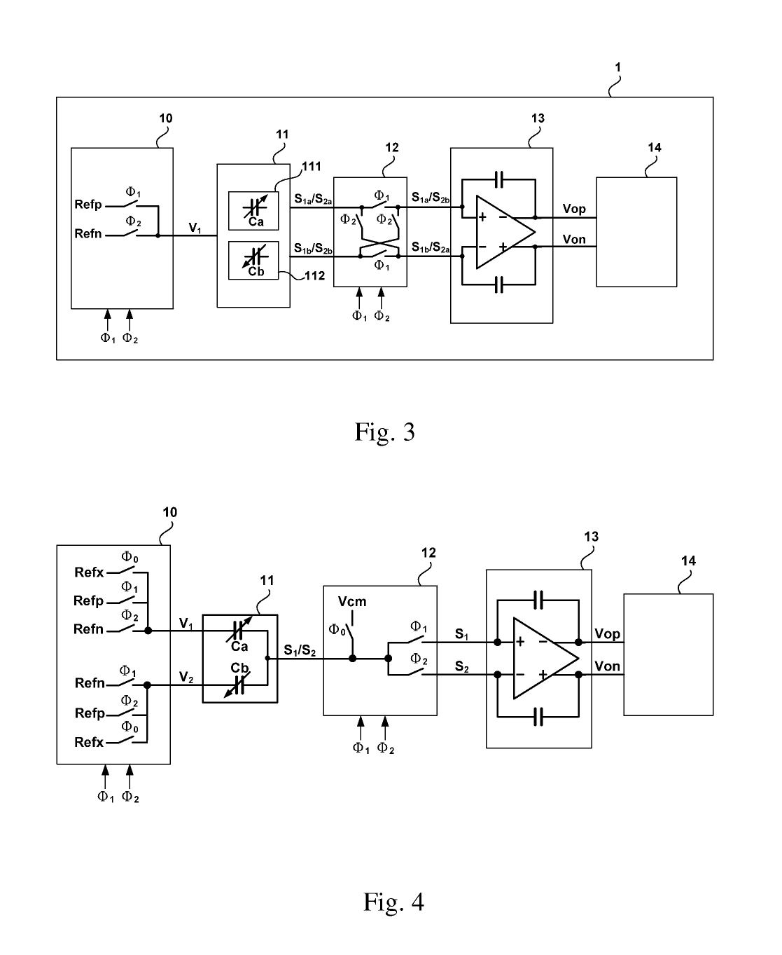

The capacitor sensing unit 11 is exemplarily a differential pair capacitors comprising a first capacitor 111 and a second capacitor 112. Taking an accelerometer for example, the accelerometer is operated for converting the relative distance of the proof mass to capacitance variation. Specifically, the capacitor sensing unit 11 comprises a first capacitor 111 and a second capacitor 112. The first capacitor 111 and second capacitor 112 are both driven through V₁/V₂ for receiving the levels of Refp and Refn switched by the first timing signal φ₁ and second timing signal φ₂. During the first timing signal φ₁, a first sensing signal S₁ is outputted through a common route, and during the second timing signal φ₂, a second sensing signal S₂ is outputted through the common route. Therefore, the S₁ and S₂ are inverting-phase signals. For raising the precision, the first capacitor 111 and second capacitor 112 could be operationally reset according to a reset timing signal φ₀ in advance. The reset timing signal φ₀, first timing signal φ1, and second timing signal φ₂ are time-sharing timing signals with regard to the period thereof. The sequence of the reset timing signal φ₀, first timing signal φ₁, and second timing signal φ₂, for example, could be φ₀→φ₁→φ₂→φ₁φ₂ . . . or φ₀→φ₁→φ₂φ₀→φ₁→φ₂ . . . . Please refer to FIG. 2. A single-transmitter dual-receiver type as shown in FIG. 3 is also taken for example. The level Refp/Refn switched by first timing signal φ₁ and second timing signal φ₂ is received through the common route V₁. The two output signals of capacitor sensing unit 11, when corresponding to the first timing signal φ₁, are the first sensing signal S₁ₐ/S_{1b}, but second sensing signal S₂ₐ/S_{2b} instead when corresponding to the second timing signal φ₂. The S₁ₐ and S₂ₐ are inverting-phase signals, and the S_{1b} and S_{2b} are inverting-phase signals.

The switching unit 12 positioned between the capacitor sensing unit 11 and differential integrator circuit 13 switches corresponding to the first timing signal φ₁ to allow a positive input terminal of the differential integrator circuit 13 receiving the first sensing signal S₁, and corresponding to the second timing signal φ₂ to allow outputting the second sensing signal S₂ which is the inverting-phase signal of S₁ to a negative input terminal of the differential integrator circuit 13. The configuration of the input terminals of the differential integrator circuit 13 could be swapped such that the negative input terminal could receive the first sensing signal S₁ during the first timing signal φ₁ and the positive input terminal receives the second sensing signal S₂. The details of the switching unit 12 is not limited to the present embodiment, but open to proper adjustments, which may depend on the electrical connection of the capacitor sensing unit 11 and differential integrator circuit 13. Preferably, the switching unit 12 may comprise two sets of switch, one of which switches according to the first timing signal φ₁ and the other switches according to the second timing signal φ₂ to control the input of the first sensing signal S₁ into an input terminal of the differential integrator circuit 13 corresponding to the first timing signal φ₁ and the input of the second sensing signal S₂ into another input terminal of the differential integrator circuit 13 corresponding to the second timing signal φ₂.

The differential integrator circuit 13 performs an integration for the inputted first sensing signal S₁ and second sensing signal S₂ to output a differential output signal related to the difference between these inputted sensing signals S₁, S₂. Preferably, the differential integrator circuit 13 comprises fully differential operational amplifiers constructed to form an integrator circuit for additionally amplifying the signals as well as the difference between the signals to enhance the sensibility, but other types of differential integrator circuit 13 could be applied in the other embodiments. Here, the differential integrator circuit 13 comprises two input terminals, at least one of which receives the first sensing signal S₁ corresponding to the first timing signal φ₁ and at least one of which receives the second sensing signal S₂ corresponding to the second timing signal φ₂. The differential integrator circuit 13 outputs differential output signals Vop and Von.

After the capacitor sensing circuit 1 differentially outputs Vop and Von through the differential integrator circuit 13, the signal processing or utilizing for the Vop and Von is carried out through the post-processing circuit 14 of any type or combination. Here, the detail structure of the post-processing circuit 14 is not limited to the present embodiment. The post-processing circuit 14 for example comprises any combination of analog-digital converter, demodulator, buffer, or other types of circuit.

Please refer to FIG. 4, which shows a block diagram of a capacitor sensing circuit of a second embodiment according to the present invention. Here the capacitor sensing circuit is of a dual-transmitter single-receiver type with two routes inputting the reset timing signal φ₀, first timing signal φ₁, and second timing signal φ₂ respectively and one single route outputting the first sensing signal S₁ and second sensing signal S₂. For clarifying the differences between the present and the previous embodiments, only the structural details of the capacitor sensing unit 11, switching unit 12 and differential integrator circuit 13 are shown.

When the level of the reset timing signal φ₀ is high, the switching unit 12 switches correspondingly to reset the first capacitor and second capacitor to Vcm.

Then, when the level of the first timing signal φ₁ is high, the capacitor sensing unit 11 outputs a first sensing signal S₁ related to the difference between the capacitance of the first capacitor Cₐ and the conjugate value of the capacitance of the second capacitor C_{b}. At this time, the switching unit 12 switches corresponding to the first timing signal φ₁ to input the first sensing signal S₁ to the positive terminal of the differential integrator circuit 13.

Then, when the level of the second timing signal φ₂ is high, the capacitor sensing unit 11 outputs a second sensing signal S₂ related to the difference between the capacitance of the second capacitor C_{b} and the conjugate value of the capacitance of the first capacitor Cₐ. At this time, the switching unit 12 switches corresponding to the second timing signal φ₂ to input the second sensing signal S₂ to the negative input terminal of the differential integrator circuit 13 and the differential integrator circuit 13 integrated S₁ and S₂ to output the differential output signals Vop and Von for the processing or utilizing of the post-processing circuit.

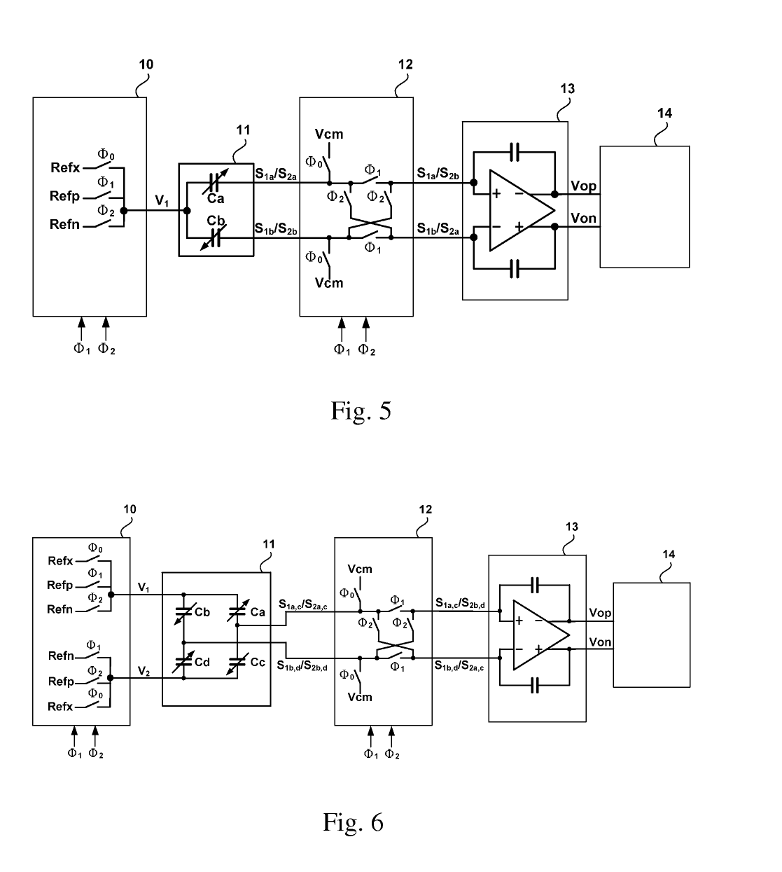

Please refer to FIG. 5, which shows a block diagram of a capacitor sensing circuit of a third embodiment according to the present invention. Here, a single-transmitter dual-receiver type with one common route inputting the reset timing signal φ₀, first timing signal φ₁, and second timing signal φ₂ and two routes outputting the first sensing signals S₁ₐ/S_{1b} and second sensing signals S₂ₐ/S_{2b} is taken for example of the capacitor sensing circuit. For clarifying the differences between the present and the first embodiments, only the structural details of the capacitor sensing unit 11, switching unit 12 and differential integrator circuit 13 are shown.

When the level of the reset timing signal φ₀ is high, the switching unit 12 switches correspondingly to reset the first capacitor and second capacitor to Vcm.

Then, when the level of the first timing signal φ₁ is high, the capacitor sensing unit 11 outputs a first sensing signal S₁ₐ related to the capacitance of the first capacitor Cₐ and then the first sensing signal S₁ₐ is inputted to the positive input terminal of the differential integrator circuit 13 through the operation of the switching unit 12. Additionally, the capacitor sensing unit 11 outputs another first sensing signal S_{1b} relating to the capacitance of the second capacitor C_{b} and then the first sensing signal S_{1b} is inputted to the negative input terminal of the differential integrator circuit 13 through the operation of the switching unit 12. After the differential integrator circuit 13 receiving these first sensing signal S₁ₐ, S_{1b}, the differential integrator circuit 13 integrates and amplifies the first sensing signals S₁ₐ, S_{1b}.

When the level of the second timing signal φ₂ is high, the capacitor sensing unit 11 outputs a second sensing signal S_{2b} related to the capacitance of the second capacitor C_{b}, and through the operation of the switching unit 12, the second sensing signal S_{2b} is reversely transmitted to the positive input terminal of the differential integrator circuit 13. The capacitor sensing unit 11 also outputs another second sensing signal S₂ₐ related to the conjugate value of the capacitance of the first capacitor Cₐ and through the operation of the switching unit 12, the second sensing signal S₂ₐ is reversely transmitted to the negative input terminal of the differential integrator circuit 13. After the differential integrator circuit 13 receives the second sensing signals S₂ₐ, S_{2b}, the second sensing signals S₂ₐ, S_{2b} are integrated and amplified for the integration of S₁ₐ/S_{1b} and S₂ₐ/S_{2b}. The differential integrator circuit 13 outputs differential output signals Vop and Von for the post-processing circuit to process or utilize. With above mentioned switching operations, in a same time, different capacitances sensed from different capacitors could contribute to a more balanced sensing result.

Please refer to FIG. 6, which shows a block diagram of a capacitor sensing circuit of a fourth embodiment according to the present invention. Here, a dual-transmitter dual-receiver type with two routes inputting the reset timing signal φ₀, first timing signal φ₁, and second timing signal φ₂ respectively and two routes outputting the first sensing signals S_{1a,c}/S_{1b,d} and second sensing signals S_{2a,c}/S_{2b,d} respectively is taken for example of the capacitor sensing circuit. For clarifying the differences between the present and the first embodiments, only the structural details of the capacitor sensing unit 11, switching unit 12 and differential integrator circuit 13 are shown. Please noted that here the capacitor sensing unit 11 comprises four capacitors, wherein a first capacitor Ca in a reversely serial connection with a third capacitor Cc and a second capacitor Cb in a reversely serial connection with a fourth capacitor Cd.

When the level of the reset timing signal φ₀ is high, the switching unit 12 switches corresponding to the reset timing signal φ₀, and the first capacitor Ca, second capacitor Cb, third capacitor Cc, and fourth capacitor Cd reset to Vcm.

When the level of the first timing signal φ₁ is high, the capacitor sensing unit 11 outputs a first sensing signal S_{1a,c}, related to the difference between the capacitance of the first capacitor Cₐ and the conjugate value of the capacitance of the third capacitor C_{c}. Through the operation of the switching unit 12, the first sensing signal S_{1a,c}, is transmitted to the positive terminal of the differential integrator circuit 13. The capacitor sensing unit 11 also outputs another first sensing signal S_{1b,d} related to the difference between the capacitance of the second capacitor C_{b} and the conjugate value of the capacitance of the fourth capacitor C_{d}. Through the operation of the switching unit 12, the first sensing signal S_{1a,c} is transmitted to the negative terminal of the differential integrator circuit 13. After the differential integrator circuit 13 receives these first sensing signals S_{1a,c}, S_{1b,d}, the first sensing signal S_{1a,c}, S_{1b,d} are integrated and amplified.

When the level of the second timing signal φ₂ is high, the capacitor sensing unit 11 outputs a second sensing signal S_{2b,d} related to the difference between the capacitance of the second capacitor C_{b} and the conjugate value of the capacitance of the fourth capacitor C_{d}. Through the operation of the switching unit 12, the second sensing signal S_{2b,d} is reversely transmitted to the positive terminal of the differential integrator circuit 13. The capacitor sensing unit 11 outputs another second sensing signal S_{2a,c} related to the difference between the capacitance of the first capacitor Cₐ and the conjugate value of the capacitance of the third capacitor C_{c}. Through the operation of the switching unit 12, the second sensing signal S_{2a,c} is reversely transmitted to the negative terminal of the differential integrator circuit 13. After the differential integrator circuit 13 receives the second sensing signal S_{2b,d}, S_{2a,c}, the second sensing signal S_{2b,d} [symbol] S_{2a,c} are integrated and amplified for the integration of the S_{1a,c}/S_{1b,d} and S_{2a,c}/S_{2b,d}. Then, the differential output signals Vop and Von are outputted for the post-processing circuit to process or utilize.

Therefore, the capacitor sensing circuit and differential integrator circuit thereof in the present invention could obtain the differential output signals related to the first capacitor and second capacitor to raise the precision and sensibility of the capacitor sensing circuit without affected by the common mode noise.

It is to be understood that these embodiments are not meant as limitations of the invention but merely exemplary descriptions of the invention with regard to certain specific embodiments. Indeed, different adaptations may be apparent to those skilled in the art without departing from the scope of the annexed claims. For instance, it is possible to add bus buffers on a specific data bus if it is necessary. Moreover, it is still possible to have a plurality of bus buffers cascaded in series.

What is claimed is:

1. A capacitor sensing circuit, comprising:
a driving unit, providing required driving signals to the capacitor sensing circuit, and comprising a first timing signal and a second timing signal which is the inverting-phase signal of the first timing signal to generate driving voltages with reverse levels;
a capacitor sensing unit, receiving the levels of the driving voltages provided by the driving unit to generate at least one first sensing signal corresponding to the first timing signal and at least one second sensing signal corresponding to the second timing signal;
a differential integrator circuit comprising two input terminals;
a switching unit, positioned between the capacitor sensing unit and the differential integrator circuit, outputting the first sensing signal to an input terminal of the differential integrator circuit and the second sensing signal to another input terminal of the differential integrator circuit, one of the input terminals of the differential integrator circuit receiving the first sensing signal and outputs a first integrated output signal, the other of the input terminals of the differential integrator circuit receiving the second sensing signal and outputs a second integrated output signal; and
a post-processing circuit, receiving the first and second integrated output signals from the differential integrator circuit for signal processing or utilizing;
wherein the first and second timing signals are time-sharing timing signals with regard to the period thereof.

2. The capacitor sensing circuit as claim 1, wherein the switching unit controls the input of the first sensing signal to an input terminal of the differential integrator circuit corresponding to the first timing signal, and the input of the second sensing signal to another input terminal of the differential integrator circuit corresponding to the second timing signal.

3. The capacitor sensing circuit as claim 1, comprising two first sensing signals and two second sensing signals, one of the first sensing signals related to the capacitance of a first capacitor, the other first sensing signal related to the conjugate value of the capacitance of a second capacitor, a second sensing signal related to the capacitance of the second capacitor, and the other second sensing signal related to the conjugate value of the capacitance of the first capacitor.

4. The capacitor sensing circuit as claim 3, wherein the switching unit controls the first sensing signals' inputs to the input terminals of the differential integrator circuit respectively corresponding to the first timing signals, and the second sensing signals' inverting inputs to the input terminals of the differential integrator circuit respectively corresponding to the second timing signals.

5. The capacitor sensing circuit as claim 1, wherein the first capacitor and the second capacitor receive the first timing signal and the second timing signal through a common route or respective routes.

6. The capacitor sensing circuit as claim 5, wherein the driving unit further comprises a third capacitor and a fourth capacitor, a first sensing signal related to the difference between the capacitance of the first capacitor and the conjugate value of the capacitance of the third capacitor is outputted corresponding to the first timing signal, and a second sensing signal related to the difference between the capacitance of the second capacitor and the conjugate value of the capacitance of the fourth capacitor is outputted corresponding to the second timing signal.

7. The capacitor sensing circuit as claim 1, wherein the first capacitor and the second capacitor are reset according to a reset timing signal, the reset timing signal and the first timing signal as well as the second timing signal are time-sharing timing signals with regard to the period thereof.

8. The capacitor sensing circuit as claim 1, wherein the differential integrator circuit comprises differential operational amplifiers constructed to form an integrator circuit.
